(19) United States
(12) Patent Application Publication
(10) Pub. No.: US 2023/0019430 A1
(43) Pub. Date: Jan. 19, 2023

(54) GAS INJECTOR AND DIFFUSION FURNACE DEVICE

(71) Applicant: CHANGXIN MEMORY TECHNOLOGIES, INC., Hefei City (CN)

(72) Inventor: Huaiqing WANG, Hefei City (CN)

(21) Appl. No.: 17/648,454

(22) Filed: Jan. 20, 2022

Related U.S. Application Data
(63) Continuation of application No. PCT/CN2021/117528, filed on Sep. 9, 2021.

(30) Foreign Application Priority Data
Jul. 13, 2021 (CN) 202110788640.3

(51) Int. Cl. H01J 37/32; H01L 21/22

(52) U.S. Cl. CPC H01J 37/32; H01L 21/22

(57) ABSTRACT

The present disclosure provides a gas injector, disposed in a diffusion furnace device, the gas injector including an inner chamber, wherein a chamber wall of the inner chamber is provided with a plurality of protrusion structures, and the plurality of protrusion structures are arranged in an array on the chamber wall.

### CROSS-REFERENCE TO RELATED APPLICATIONS

This is a continuation of International Application No. PCT/CN2021/117528, filed on Sep. 9, 2021, which claims the priority to Chinese Patent Application No. 202110788640.3, titled “GAS INJECTOR AND DIFFUSION FURNACE DEVICE” and filed on Jul. 13, 2021. The entire contents of International Application No. PCT/CN2021/117528 and Chinese Patent Application No. 202110788640.3 are incorporated herein by reference.

### TECHNICAL FIELD

The present disclosure relates to the technical field of semiconductor manufacturing devices, and in particular, to a gas injector and a diffusion furnace device.

### BACKGROUND

A semiconductor furnace device component is a quartz-textured component that supplies a specific gas into a reaction chamber. During the process, the gas is introduced into the reaction chamber through an injector for reaction and forming a membrane layer on a surface of a wafer.

However, during use of an existing gas injector, while a gas is introduced into a reaction chamber for reaction and forming a membrane layer on a surface of a wafer, a membrane layer with a same texture and tight arrangement is formed on a smooth inner surface of a gas injector. The membrane layer gradually becomes thicker as the number of reactions increases. In addition, due to the tight arrangement of the membrane layer, there is small room for ductility during heating and expansion, and mutual extrusion within the membrane layer generates stress. As the stress increases due to an increase in a thickness of the membrane layer, when an endurance limit of the membrane layer is reached, the membrane layer may crack and peel off from an inner surface of an inner chamber of the gas injector and is injected into the reaction chamber with the gas, resulting in contamination of the wafer, and greatly affecting a product yield.

### SUMMARY

According to one aspect of embodiments of the present disclosure, a gas injector is provided, disposed in a diffusion furnace device, the gas injector comprising an inner chamber, wherein a chamber wall of the inner chamber is provided with a plurality of protrusion structures, and the plurality of protrusion structures are arranged in an array on the chamber wall.

According to another aspect of the embodiments of the present disclosure, a diffusion furnace device is provided, wherein the diffusion furnace device includes the gas injector provided in the present disclosure and described in the foregoing implementation.

### BRIEF DESCRIPTION OF THE DRAWINGS

FIG. 1 is a schematic structural diagram of a gas injector according to an exemplary implementation;

FIG. 2 is an axial cross-sectional view of the gas injector shown in FIG. 1;

FIG. 3 is a front view of FIG. 2;

FIG. 4 is a schematic plan view of FIG. 3;

FIG. 5 is an enlarged view of a part A in FIG. 4;

FIG. 6 is a schematic diagram showing that a force is applied to a membrane layer of a protrusion structure of the gas injector shown in FIG. 1;

FIG. 7 a radial cross-sectional view of the gas injector shown in FIG. 2;

FIG. 8 is a schematic diagram of comparison between an exfoliation of a gas injector provided in the present disclosure and an exfoliation of a gas injector without a protrusion structure formed on a chamber wall;

FIG. 9 is a schematic plan view of a part of an inner chamber of a gas injector according to another exemplary implementation;

FIG. 10 to FIG. 13 are each a partial enlarged view of an inner chamber of a gas injector according to another exemplary implementation; and

FIG. 14 and FIG. 15 are each an axial cross-sectional view of a gas injector according to another exemplary implementation.

### DETAILED DESCRIPTION

Exemplary embodiments will be described below more comprehensively with reference to the accompanying drawings. However, the exemplary embodiments can be implemented in a plurality of forms and should not be construed as being limited to embodiments described herein. On the contrary, these embodiments are provided such that the present disclosure is more comprehensive and complete, and fully conveys the concept of the exemplary embodiments to those skilled in the art. The same reference numerals in the figures indicate the same or similar structures, and thus their detailed descriptions will be omitted.

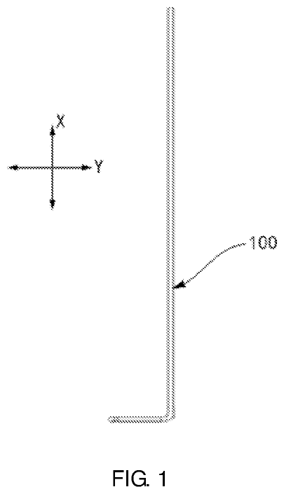

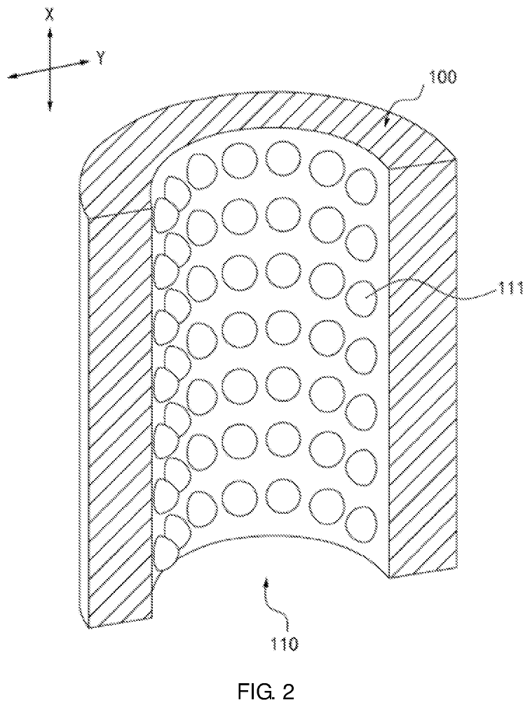

Referring to FIG. 1 and FIG. 2, FIG. 1 representatively shows a schematic structural diagram of a specific implementation of a gas injector 100 provided in the present disclosure; FIG. 2 representatively shows an axial cross-sectional view of FIG. 1, and specifically shows merely an axial cross-sectional view of a section of the structure of the gas injector 100. In the exemplary implementation, the gas injector provided in the present disclosure is described using an example in which it is applied to a diffusion furnace device. It is understandable for those skilled in the art that, in order to apply the relevant design of the present disclosure to other types of furnace devices, various modifications, additions, substitutions, deletions, or other changes may be made to the following specific implementations, but such changes are still within the scope of the principle of the gas injector provided in the present disclosure.

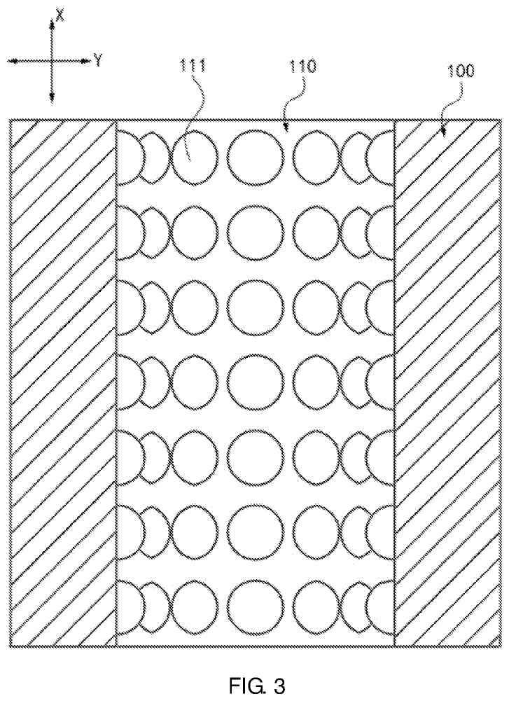

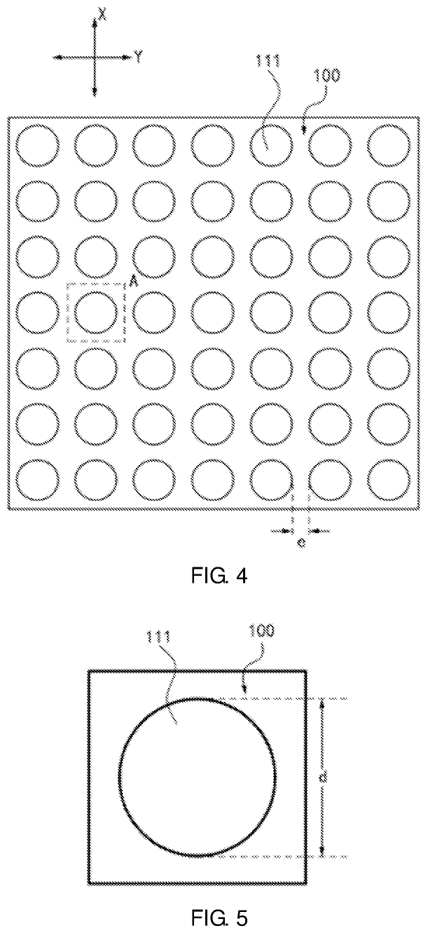

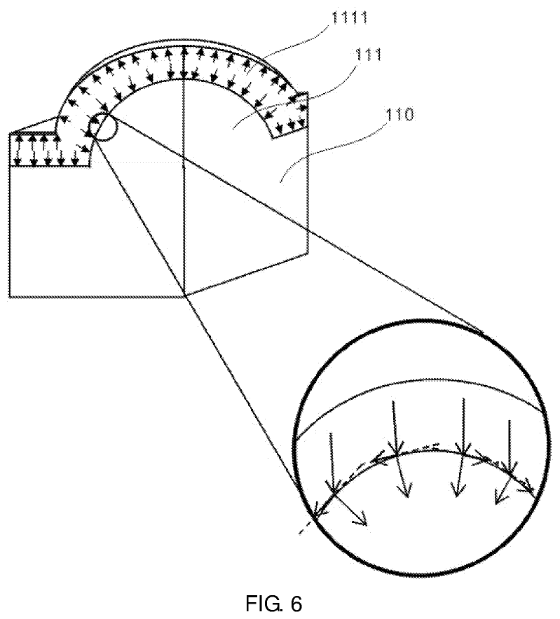

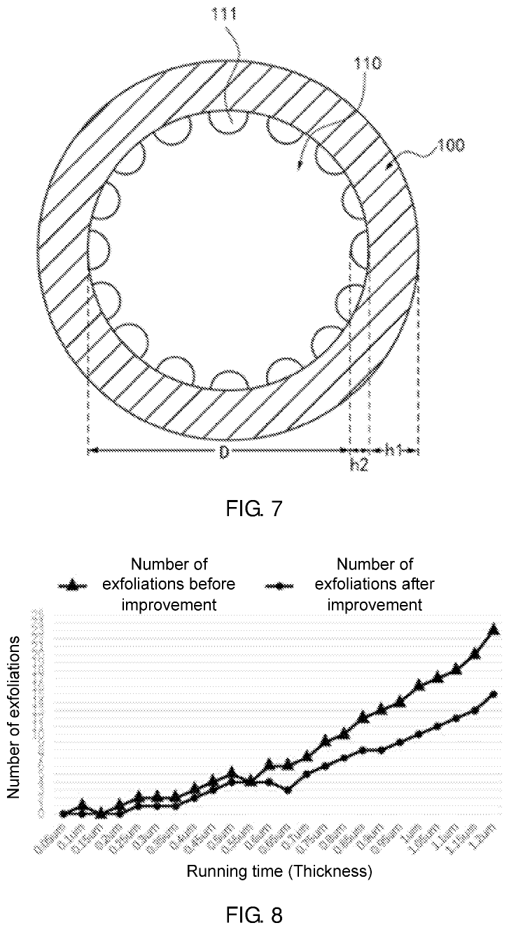

As shown in FIG. 2, in this implementation, the gas injector 100 provided in the present disclosure comprises an inner chamber 110. Referring to FIG. 3 to FIG. 7, FIG. 3 representatively shows a front view of FIG. 2; FIG. 4 representatively shows a schematic plan view of FIG. 3; FIG. 5 representatively shows an enlarged view of a part A in FIG. 4; FIG. 6 representatively shows a schematic diagram showing that a force is applied to a membrane layer of a protrusion structure of a gas injector; and FIG. 7 representatively shows a cross-sectional view in a radial direction y of the gas injector 100 shown in FIG. 2. Structures, arrangement manners, and functional relationships of main component portions of the gas injector provided in the present disclosure are described in detail below with reference to the accompanying drawings.

As shown in FIG. 2 and FIG. 3, in this implementation, a chamber wall of the inner chamber 110 of the gas injector 100 is provided with a plurality of protrusion structures. In this way, these protrusion structures can be used to increase a surface area of the chamber wall. Through the foregoing design, the present disclosure can increase an expansion space of a membrane layer formed on the chamber wall. In this way, during the formation of a membrane layer (for example, a membrane layer made of silicon oxide, aluminum oxide, zirconium oxide, or polycrystalline silicon) on the inner wall of the gas sprayer, a membrane is unevenly formed on the inner wall based on the protrusion structure, such that the stress is released and penetration between the membrane layer and the chamber wall can be reduced, thereby reducing etching damage to the chamber wall. In addition, the protrusion structure can increase strength of the chamber wall and increase a force bearing capability of the chamber wall, such that the chamber wall is not easily damaged. Further, the protrusion structure can increase an area of an inner surface of the chamber wall, expand an adhesion space of the membrane layer, reduce peeling of the membrane layer caused by stress release due to temperature changes, and alleviate generation of an exfoliation, thereby increasing a service life of the gas injector. Moreover, through the design of the protrusion structure, the present disclosure can further reduce maintenance costs, improve a yield, and reduce product scrap loss.

Optionally, in this implementation, an end surface of the protrusion structure 111 may be in an arc shape. In this way, when a membrane layer is formed on the end surface of the protrusion structure 111, a force generated by heating and expansion of the inner surface of the membrane layer is decomposed. Therefore, a capability of the inner surface of the membrane layer formed on the protrusion structure 111 to withstand pressure is greatly increased compared with that of a flat end surface. In other implementations, the end surface of the protrusion structure 111 may alternatively be flat, which is not limited to this implementation.

Optionally, as shown in FIG. 2 to FIG. 4, in this implementation, the plurality of protrusion structures 111 may be substantially arranged in an array on the chamber wall. Through the design, the present disclosure can further increase a surface area of the chamber wall, thereby further increasing an expansion space of the membrane layer formed on the chamber wall.

Further, as shown in FIG. 2 to FIG. 4, based on the design in which the plurality of protrusion structures 111 are arranged in an array, in this implementation, in these protrusion structures 111 that are arranged in an array, a plurality of protrusion structures 111 located in a same row may be arranged at intervals along a circumferential direction of the gas injector 100. In other implementations, the plurality of protrusion structures 111 located in the same row may alternatively be arranged in a direction relatively inclined to a plane (that is, a radial plane Y) where the circumferential direction of the gas injector 100 lies, which is not limited to this implementation.

Further, as shown in FIG. 2 to FIG. 4, based on the design in which the plurality of protrusion structures 111 are arranged in an array, in this implementation, in these protrusion structures 111 that are arranged in an array, a plurality of protrusion structures 111 located in a same column may be arranged at intervals along an axial direction X of the gas injector 100. In other implementations, the plurality of protrusion structures 111 located in a same column may alternatively be arranged in a direction relatively inclined to the axial direction X of the gas injector 100, which is not limited to this implementation.

Further, as shown in FIG. 2 to FIG. 4, based on the design in which the plurality of protrusion structures 111 are arranged in an array, in this implementation, in these protrusion structures 111 that are arranged in an array, a spacing between any protrusion structure 111 and another adjacent protrusion structure 111 in a same column is equal to a spacing e between the protrusion structure 111 and another adjacent protrusion structure 111 in a same row, such that the plurality of protrusion structures 111 are arranged in an array on the chamber wall uniformly. In other implementations, when the plurality of protrusion structures 111 are arranged in an array, a spacing e between protrusion structures 111 located in a same row alternatively may not be equal to a spacing between protrusion structures 111 located in a same column. In addition, a plurality of spacings e between a plurality of pairs of adjacent protrusion structures 111 located in a same row also may not be equal, and a plurality of pairs of adjacent protrusion structures 111 located in a same column also may not be equal, which are not limited to this implementation.

Further, as shown in FIG. 4 to FIG. 6, based on the design in which the plurality of protrusion structures 111 are arranged in an array uniformly, in this implementation, the end surface of the protrusion structure 111 may be in an arc shape, for example, may be substantially of a hemispherical structure. In this way, the protrusion structure 111 of the inner chamber 110 greatly increases the surface area of the inner chamber 110 and greatly expands an adhesion space of the deposited membrane layer, and a force generated by heating and expansion of the membrane layer formed on the end surface in an arc shape of the protrusion structure 111 is decomposed, such that a capability of the membrane layer to withstand pressure is greatly increased, thereby greatly reducing a possibility of generating an exfoliation. In addition, as shown in FIG. 6, a force at an intersection of the deposited membrane layer and the chamber wall is decomposed, which can alleviate a diffusion phenomenon that occurs at the intersection of the membrane layer and the end surface of the protrusion structure 111 when the deposited membrane layer expands with an increase in temperature. Therefore, penetration at the intersection surface between the membrane layer and the inner wall of the inner chamber 110 is reduced, tube shell (chamber wall) cracking caused when the device performs a cleaning function is reduced, a service life of the gas injector is increased, and a product yield is ensured. On the basis of this, a ratio of a diameter d of the protrusion structure 111 to a spacing between two adjacent protrusion structures 111 located in a same column is 1:1 to 3:1. That is, a ratio of a diameter d of the protrusion structure 111 to a spacing e between two adjacent protrusion structures 111 located in the same row is 1:1 to 3:1, for example, is 1:1, 1.5:1, 2:1, or 3:1. In other implementations, when the plurality of protrusion structures 111 are arranged in an array uniformly, a ratio of a diameter d of the protrusion structure 111 and a spacing e between two adjacent (in a same row or in a same column) protrusion structures 111 may alternatively be less than 1:1, or may be greater than 3:1, for example, may be 0.8:1 or 3.5:1, which is not limited to this implementation.

Further, as shown in FIG. 4 to FIG. 7, in this implementation, the inner chamber 110 is of a cylindrical chamber structure, the protrusion structure 111 may be of a hemispherical structure, and a ratio of a diameter D of a corresponding cylinder of the inner chamber 110 to a diameter d of the protrusion structure 111 may be 2:1 to 4:1, for example, may be 2:1, 3:1, 3.5:1, or 4:1. In other implementations, when the inner chamber 110 of the gas injector 100 is of a cylindrical chamber structure, and the protrusion structures include hemispherical protrusion structures 111, a ratio of a diameter D of a corresponding cylinder of the inner chamber 110 to a diameter d of the protrusion structure 111 may alternatively be less than 2:1, or may be greater than 4:1, for example, may be 1.9:1 or 5:1 but needs to be greater than 1:1, which is not limited to this implementation.

It should be noted that, in the description of this specification, the hemispherical shape of the protrusion structure 111 is described in such a way because the protrusion structure 111 is provided on the chamber wall of the inner chamber 110 with an curved surface in an arc shape (such as a cylindrical surface). However, a standard hemispherical shape is suitable only for defining a structure provided on a plane. Therefore, the description of the protrusion structure 111 being in the hemispherical shape is an approximation of the shape and structure of the protrusion structure 111. For example, as may be defined, a height of the protrusion structure 111, that is, a farthest distance from the protrusion structure 111 to a position of the chamber wall provided therein is equal to a corresponding diameter of the hemispherical protrusion structure 111. On the basis of this, due to curvature of the chamber wall, a diameter of a circumference of the protrusion structure 111 on the chamber wall is slightly less than a true diameter of the protrusion structure 111. For ease of understanding and description, the foregoing diameter is collectively referred to as the diameter d of the protrusion structure 111.

Optionally, as shown in FIG. 7, in this implementation, a ratio of a thickness h1 of the chamber wall of the inner chamber 110 of the gas injector 100 to a height h2 of the protrusion structure may be 1:1 to 3:1, for example, may be 1:1, 2:1, 2.5:1, or 3:1. In this way, stress of the deposited membrane layer is alleviated, the membrane layer is prevented from having cracks during repeated expansion and contraction with the process temperature, thereby avoiding a phenomenon of serious membrane layer peeling. When the protrusion structure 111 is in the hemispherical shape, the height h2 of the protrusion structure 111 may alternatively be approximately understood as a radius of the protrusion structure 111 (that is, a half of the diameter d of the hemispherical protrusion structure 111). In other implementations, a ratio of a thickness h1 of the chamber wall of the inner chamber 110 of the gas injector 100 to a height of the protrusion structure may alternatively be less than 1:1, or may be greater than 3:1, for example, may be 0.8:1 or 3.5:1, which is not limited to this implementation.

In various other possible implementations conforming to the design concept of the present disclosure, when the chamber wall of the inner chamber is provided with a plurality of protrusion structures, shapes of the plurality of protrusion structures may be the same regardless of the arrangement of these protrusion structures. Further, heights of the plurality of protrusion structures may be the same. Certainly, depending on different structures of gas injectors, or in order to meet formation needs of different membrane layers, when there are a plurality of protrusion structures, shapes of the plurality of protrusion structures alternatively may not be completely the same, and heights thereof may not be completely the same, which is not limited thereto.

It should be noted that, the gas injector 100 may have an end. On the basis of this, the end may be open, so as to form a jet hole communicating with the inner chamber 110, that is, a single-hole gas injector. Alternatively, the end may be closed, and a plurality of jet holes communicating with the inner chamber 110 are provided on a part of the gas injector 100 close to the end, that is, a porous gas injector.

Referring to FIG. 4 and FIG. 5, in a square region shown in FIG. 5, a circle (which may be considered as orthographic projection of the protrusion structure 111 on the chamber wall after planarization and unfolding), that is, the diameter of the circumference of the protrusion structure 111, is approximately equal to the diameter d of the protrusion structure 111, a spacing between the circle and each side edge of the square on each side can be defined as a half of the spacing e of the two adjacent protrusion structures 111, thereby ensuring that the deposited membrane layer has an ideal deposition space, and alleviating stress caused by internal mutual extrusion. On the basis of this, that the plurality of protrusion structures 111 are arranged in an array uniformly is used as an example. In terms of the square region having the foregoing dimension relationship, for an inner surface improved by using this embodiment of the present disclosure, an area of a hemispherical surface is increased and an area of a circular plane is decreased in a unit region of the square compared with a smooth surface of the chamber wall of the gas injector without the protrusion structure formed in the chamber wall. In this way, the surface area of the chamber wall improved by using this embodiment of the present disclosure is increased.

Specifically, during use of the gas injector, while a gas is introduced into the reaction chamber to react and form a membrane layer on a surface of a wafer, a membrane layer with a same texture is formed on the chamber wall of the inner chamber of the gas injector. The following compares the chamber wall improved by using this embodiment of the present disclosure with a chamber wall on which no protrusion structure is formed, to describe an incremental magnitude of a deposition amount of the membrane layer:

Based on the above content, an area of the smooth surface in the foregoing unit region in the solution of forming no protrusion structure on the chamber wall is:

S₁=W².

The surface area of the chamber wall improved by using this embodiment of the present disclosure in the foregoing unit region is:

S₂=W²−πR²+4πR²/2=W²+πR².

Based on this, through improvement by the present disclosure, the area increased in the foregoing unit region is:

ΔS=S₂−S₁=πR².

W is a side length of the unit region of the square, and W=d+e. R is the radius of the hemispherical protrusion structure 111, and R=d/2.

On the basis of this, for the unit region shown in FIG. 5, the deposition amount of the membrane layer with the smooth surface in the solution in which no protrusion structure is formed on the chamber wall is:

V₁=H*S₁=H*W².

To facilitate comparison, a same membrane layer deposition thickness is used as an example, and a membrane layer deposition amount of the chamber wall improved by using this embodiment of the present disclosure in the foregoing unit region is:

V₂=H*S₂=H*(W²+πR²).

Based on this, through improvement by the present disclosure, an increment of the deposition amount of the membrane layer in the foregoing unit region is:

ΔV=V₂−V₁=H*πR².

H is the thickness of the membrane layer deposited on the inner surface of the chamber wall.

Based on the above content, compared with the solution in which no protrusion structure is formed on the chamber wall, the foregoing first implementation of the present disclosure is used as an example, and the incremental magnitude of the deposition amount of the membrane layer on the chamber wall improved by using this embodiment of the present disclosure is:

ΔV/V₁*100%=(H*πR²)/(H*W²)*100%=πR²/W²*100%.

On the basis of this, refer to FIG. 8. FIG. 8 representatively shows a schematic diagram of comparison between an exfoliation of a gas injector provided in the present disclosure and an exfoliation of a gas injector without a protrusion structure formed on a chamber wall. Based on the description of the foregoing implementation, a specific practical example of the gas injector provided in the present disclosure is described below with reference to FIG. 8.

In the specific practical example, the design of the foregoing first implementation of the present disclosure is used for the gas injector. The diameter d of the hemispherical protrusion structure is 2 mm, and the radius R of the protrusion structure is 1 mm. The spacing e between two adjacent protrusion structures located in a same row (or a same column) is 1 mm. In this case, the side length of the unit region of the foregoing square is:

W=d+e=2 mm+1 mm=3 mm.

Based on this, with reference to the formula for the incremental magnitude of the foregoing membrane layer deposition amount, it can be learned that the incremental magnitude of the membrane layer deposition amount of the chamber wall of the inner chamber of the gas injector improved by using this embodiment of the present disclosure is specifically:

πR²/W²*100%=π*⅓²*100%≈34.9%.

The following comparison illustrates replacement costs of gas injectors:

Based on the specific practical example, based on the comparison of the thickness of the membrane layer on the inner surface of the chamber wall of the inner chamber of the gas injector before and after the improvement, assuming that the chamber needs to be cleaned once when the thickness of the membrane layer on the inner surface reaches 1 μm, a required running time for each accumulated 0.1 μm thickness of the membrane layer in the solution in which no protrusion structure is formed on the chamber wall is M1 days. After the improvement by using this embodiment of the present disclosure, the required running time for each accumulated 0.1 μm thickness of the membrane layer is M2 days, and the injector is replaced once every N times of chamber cleaning.

Based on the above content, because an area of the inner surface of the injector after the improvement by using this embodiment of the present disclosure is increased by 34.9%, the running time corresponding to each accumulated membrane layer of 0.1 μm thickness is increased by 34.8% accordingly. Therefore:

M₂=(100%+34.9%)*M₁=134.9%*M₁.

That is, a replacement cycle for the solution in which no protrusion structure is formed on the chamber wall is:

t₁=10*M₁*N.

The replacement cycle obtained after the improvement by using this embodiment of the present disclosure is:

t₂=10*M₂*N=10*M₁*N*134.8%=134.8%*t₁.

Based on the above content, the number of replacements per year for the solution in which no protrusion structure is formed on the chamber wall is:

T₁=365/t₁;

The number of replacements per year after the improvement by using this embodiment of the present disclosure is:

T₂=365/t₂;

Therefore, a degree of reduction of replacement costs of the gas injector improved by using this embodiment of the present disclosure is:

(T₁−T₂)/T₁=(365/t₁−365/t₂)/365/t₁≈25.8%.

In summary, based on the foregoing design of the present disclosure, the annual replacement costs of the gas injector will be reduced by approximately 25.8%.

The following comparison illustrates maintenance duration of the gas injector:

A replacement operation duration of the gas injector is P days, and a replacement operation duration of the gas injector improved by using this embodiment of the present disclosure will be reduced, compared with that in the solution in which no protrusion structure is formed on the chamber wall, by:

(T₁−T₂)*P days.

Therefore, after the improvement by using this embodiment of the present disclosure, compared with the solution in which no protrusion structure is formed on the chamber wall, a degree of reduction of the device maintenance duration is:

(T₁*P−T₂*P)/T₁*P*100%=(1−T₂/T₁)*100%≈25.8%

In summary, based on the foregoing design of the present disclosure, the maintenance time of the gas injector is reduced by 25.8%.

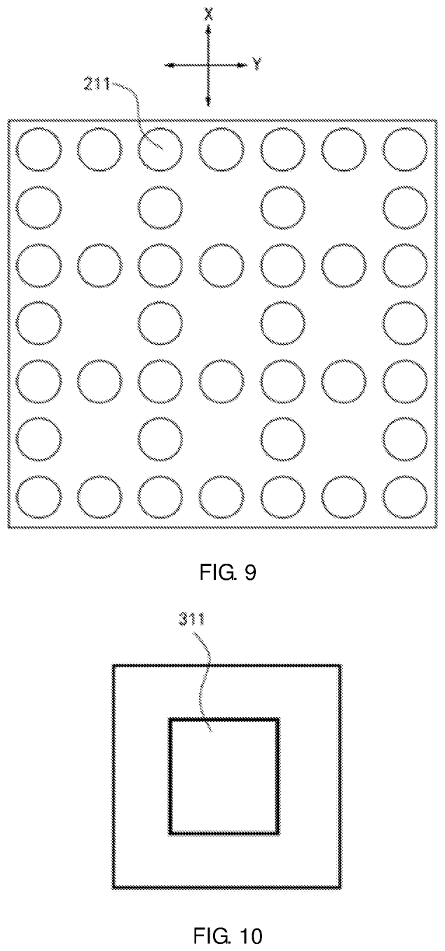

Based on the foregoing description of the first implementation of the gas injector, a second implementation thereof is described below. Referring to FIG. 9, FIG. 9 representatively shows a schematic plan view of a part of an inner chamber of a gas injector in a second implementation of the gas injector. The design of the gas injector provided in the present disclosure in the second implementation that is different from other implementations is described in detail below with reference to FIG. 9.

As shown in FIG. 9, different from the design in the first implementation in which the plurality of protrusion structures 111 are arranged in an array uniformly, in this implementation, a plurality of protrusion structures 211 may be arranged in an array in a non-uniform manner. In other implementations, when there are a plurality of protrusion structures, these protrusion structures may alternatively be arranged in other manners or irregularly, which is not limited to this implementation.

Based on the foregoing description of the first implementation of the gas injector, a third implementation thereof is described below. Referring to FIG. 10, FIG. 10 representatively shows a partial enlarged view of an inner chamber of a gas injector in a third implementation of the gas injector. The design of the gas injector provided in the present disclosure in the third implementation that is different from other implementations is described in detail below with reference to FIG. 10.

As shown in FIG. 10, different from the design in the first implementation in which the protrusion structure 111 is hemispherical, in this implementation, a protrusion structure 311 may be substantially of a rectangular column shape.

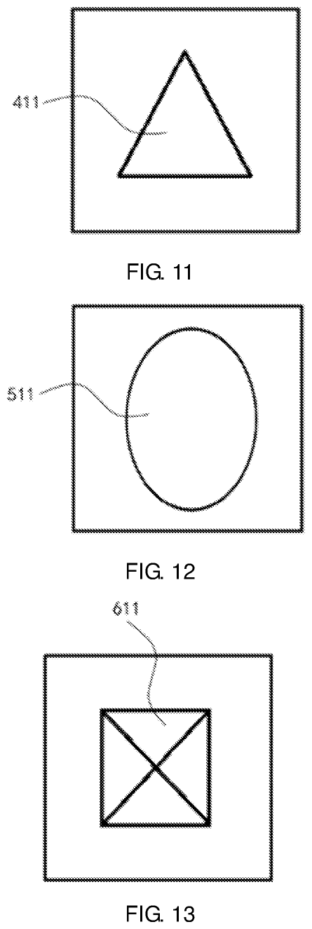

Based on the foregoing description of the first implementation of the gas injector, a fourth implementation thereof is described below. Referring to FIG. 11, FIG. 11 representatively shows a partial enlarged view of an inner chamber of a gas injector in a fourth implementation of the gas injector. The design of the gas injector provided in the present disclosure in the fourth implementation that is different from other implementations is described in detail below with reference to FIG. 11.

As shown in FIG. 11, different from the first implementation in which the protrusion structure 111 is hemispherical, in this implementation, a protrusion structure 411 may be substantially of a triangular prism shape.

Based on the foregoing description of the first implementation of the gas injector, a fifth implementation thereof is described below. Referring to FIG. 12, FIG. 12 representatively shows a partial enlarged view of an inner chamber of a gas injector in a fifth implementation of the gas injector. The design of the gas injector provided in the present disclosure in the fifth implementation that is different from other implementations is described in detail below with reference to FIG. 12.

As shown in FIG. 12, different from the design in the first implementation in which the protrusion structure 111 is hemispherical, in this implementation, a protrusion structure 511 may be substantially of a semi-ellipsoid shape.

Based on the foregoing description of the first implementation of the gas injector, a sixth implementation thereof is described below. Referring to FIG. 13, FIG. 13 representatively shows a partial enlarged view of an inner chamber of a gas injector in a sixth implementation of the gas injector. The design of the gas injector provided in the present disclosure in the sixth implementation that is different from other implementations is described in detail below with reference to FIG. 13.

As shown in FIG. 13, different from the design in the first implementation in which the protrusion structure 111 is hemispherical, in this implementation, a protrusion structure 611 may be substantially of a quadrangular pyramid shape.

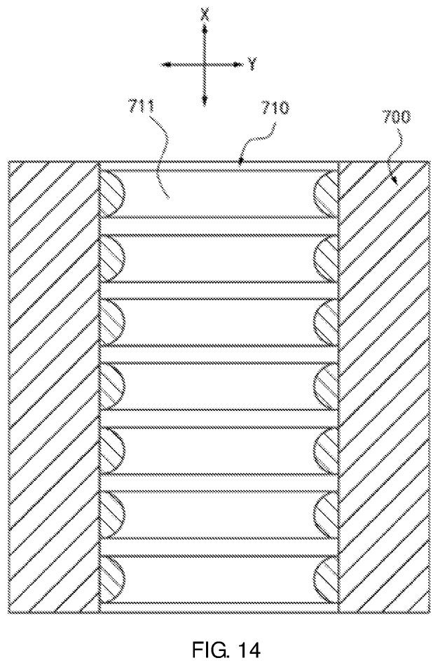

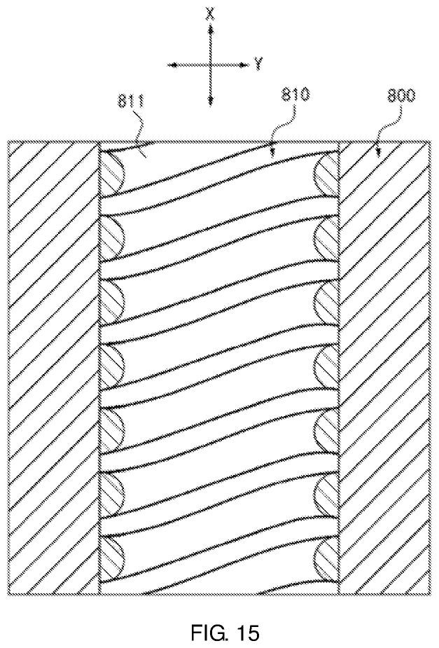

Based on the foregoing description of the first implementation of the gas injector, a seventh implementation thereof is described below. Referring to FIG. 14, FIG. 14 representatively shows an axial cross-sectional view of a gas injector in a seventh implementation of the gas injector. The design of the gas injector provided in the present disclosure in the seventh implementation that is different from other implementations is described in detail below with reference to FIG. 14.

As shown in FIG. 14, different from the design in the first implementation in which the protrusion structures include the protrusion structures 111, in this implementation, the protrusion structures may include convex rings 711. For example, the convex rings 711 may be arranged along a radial direction Y of a gas injector 700 around the chamber wall of the inner chamber, the protrusion structures may include a plurality of convex rings 711, and these convex rings 711 may be arranged at intervals along an axial direction X of the gas injector 700.

Optionally, as shown in FIG. 14, in this implementation, a cross section of the convex ring 711 may be substantially semicircular. In other implementations, the cross section of the convex ring 711 may alternatively be of other shapes, for example, a rectangle, a triangle, or a semi-ellipse, which is not limited to this implementation.

Based on the foregoing description of the first implementation of the gas injector, an eighth implementation thereof is described below. Referring to FIG. 15, FIG. 15 representatively shows an axial cross-sectional view of a gas injector in an eighth implementation of the gas injector. The design of the gas injector provided in the present disclosure in the eighth implementation that is different from other implementations is described in detail below with reference to FIG. 15.

As shown in FIG. 15, different from the design in the seventh implementation in which the protrusion structures include the protrusion structures 111, in this implementation, the protrusion structures may include spiral structures 811. For example, a spiral direction of the spiral structures 811 may extend along an axial direction X of a gas injector 800, and spiral arms of the spiral structures 811 may be spirally arranged on a chamber wall of an inner chamber along a radial direction Y of the gas injector 800.

Optionally, as shown in FIG. 15, in this implementation, a cross section of the spiral arm of the spiral structure 811 may be substantially semicircular. In other implementations, the cross section of the spiral arm of the spiral structure 811 may alternatively be of other shapes, for example, a rectangle, a triangle, or a semi-ellipse, which is not limited to this implementation.

It should be noted that, in other implementations, in addition to the bumps (hemispherical protrusion structures), the convex rings, and the spiral structures in the foregoing implementation, the protrusion structures may further include ribs, pleated structures, and corrugated structures, and may include at least two of the foregoing structures, which are not limited to the foregoing implementation.

In summary, according to the gas injector provided in the present disclosure, a protrusion structure is provided on a chamber wall of an inner chamber thereof, such that a surface area of the chamber wall of the inner chamber is increased, thereby increasing an expansion space of a membrane layer formed on the chamber wall. Based on this, the present disclosure can reduce peeling of the membrane layer caused by stress release due to temperature changes, and alleviate generation of an exfoliation.

Based on the detailed descriptions of the exemplary implementations of the gas injector provided in the present disclosure, an exemplary implementation of a diffusion furnace device provided in the present disclosure is described below.

In this implementation, the diffusion furnace device provided in the present disclosure includes a gas injector, and the gas injector is the injector provided in the present disclosure and described in detail in the foregoing implementations.

In summary, in the diffusion furnace device provided in the present disclosure, the use of the foregoing design of the gas injector provided in the present disclosure can reduce generation of exfoliation, thereby alleviating a problem of contamination caused by the exfoliation to a wafer, and greatly improving a product yield.

The present disclosure is described above with reference to several typical implementations. It should be understood that the terms used herein are intended for illustration, rather than limiting. The present disclosure may be specifically implemented in many forms without departing from the spirit or essence of the present disclosure. Therefore, it should be understood that the above embodiments are not limited to any of the above-mentioned details, but should be broadly interpreted according to the spirit and scope defined by the appended claims. Therefore, any changes and modifications falling within the claims or the equivalent scope thereof should be covered by the appended claims.

1. A gas injector, disposed in a diffusion furnace device, the gas injector comprising an inner chamber, a chamber wall of the inner chamber being provided with a plurality of protrusion structures, and the plurality of protrusion structures being arranged in an array on the chamber wall.

2. The gas injector according to claim 1, wherein an end surface of the protrusion structure is in an arc shape.

3. The gas injector according to claim 1, wherein in the plurality of protrusion structures arranged in the array, a plurality of the protrusion structures located in a same row are arranged along a circumferential direction of the gas injector.

4. The gas injector according to claim 1, wherein in the plurality of protrusion structures arranged in the array, a plurality of the protrusion structures located in a same column are arranged along an axial direction of the gas injector.

5. The gas injector according to claim 1, wherein in the plurality of protrusion structures arranged in the array, a spacing between any of the protrusion structures and another adjacent protrusion structure in a same column is equal to a spacing between the any of the protrusion structures and another adjacent protrusion structure in a same row, such that the plurality of protrusion structures are arranged in the array on the chamber wall uniformly.

6. The gas injector according to claim 5, wherein the protrusion structure is of a hemispherical structure, and a ratio of a diameter of the protrusion structure to a spacing between two adjacent protrusion structures located in a same column is 1:1 to 3:1.

7. The gas injector according to claim 1, wherein the inner chamber is of a cylindrical chamber structure, the protrusion structure is of a hemispherical structure, and a ratio of a diameter of a corresponding cylinder of the inner chamber to a diameter of the protrusion structure is 2:1 to 4:1.

8. The gas injector according to claim 1, wherein the chamber wall of the inner chamber is provided with the plurality of protrusion structures, and the plurality of protrusion structures have a same shape.

9. The gas injector according to claim 1, wherein the chamber wall of the inner chamber is provided with the plurality of protrusion structures, and the plurality of protrusion structures have a same height.

10. The gas injector according to claim 1, wherein the protrusion structure comprises at least one of a bump, a rib, a convex ring, a pleated structure, a corrugated structure, or a spiral structure.

11. The gas injector according to claim 1, wherein a ratio of a thickness of the chamber wall of the inner chamber to a height of the protrusion structure is 1:1 to 3:1.

12. The gas injector according to claim 1, wherein an end of the gas injector is provided with a jet hole, and the jet hole communicates with the inner chamber.

13. The gas injector according to claim 1, wherein an end of the gas injector is closed, the gas injector is provided with a plurality of jet holes, the plurality of jet holes are provided at a position of the gas injector close to the end respectively, and the plurality of jet holes communicate with the inner chamber respectively.

14. A diffusion furnace device, wherein the diffusion furnace device comprises the gas injector according to claim 1.
